(19) United States
(12) Patent Application Publication
(10) Pub. No.: US 2024/0105890 A1
(43) Pub. Date: Mar. 28, 2024

(54) OPTOELECTRONIC DEVICE WITH AXIAL-TYPE THREE-DIMENSIONAL LIGHT-EMITTING DIODES

(71) Applicant: Aledia, Echirolles (FR)

(72) Inventors: Olga Kryliouk, Fort Myers, FL (US); Mehdi Daanoune, Renage (FR); Jérôme Napierala, Saint Egrève (FR)

(73) Assignee: Aledia, Echirolles (FR)

(21) Appl. No.: 18/267,417

(22) PCT Filed: Dec. 2, 2021
(86) PCT No.: PCT/EP2021/083862

§ 371 Date: Jun. 14, 2023

(30) Foreign Application Priority Data
Dec. 17, 2020 (FR) FR2013516

(51) Int. Cl. H01L 33/58; H01L 27/15; H01L 33/24

(52) U.S. Cl. CPC H01L 33/58; H01L 27/156; H01L 33/24; H01L 2933/0083

(57) ABSTRACT

An optoelectronic device including an array of axial light-emitting diodes. The light-emitting diodes each include an active area configured to emit an electromagnetic radiation having an emission spectrum including a maximum at a first wavelength. The array forms a photonic crystal configured to be able to form three resonance peaks amplifying the intensity of said electromagnetic radiation at at least second, third, and fourth wavelengths.

This patent application claims the priority of the French patent application FR20/13516 which will be considered as an integral part of this description.

### TECHNICAL BACKGROUND

The present disclosure concerns an optoelectronic device, particularly a display screen or an image projection device, comprising light-emitting diodes made up of semiconductor materials, and their manufacturing methods.

### PRIOR ART

A light-emitting diode based on semiconductor materials generally comprises an active area which is the region of the light-emitting diode from which most of the electromagnetic radiation supplied by the light-emitting diode is emitted. The structure and the composition of the active area are configured to obtain an electromagnetic radiation having the desired properties. In particular, it is generally desired to obtain a narrow-spectrum electromagnetic radiation, ideally substantially monochromatic.

Optoelectronic devices comprising axial-type three-dimensional light-emitting diodes, that is, light-emitting diodes each comprising a three-dimensional semiconductor element extending along a preferred direction and comprising the active area at an axial end of the three-dimensional semiconductor element, are here more particularly considered.

Examples of three-dimensional semiconductor elements are microwires or nanowires comprising a semiconductor material based on a compound mainly comprising at least one group-III element and one group-V element (for example, gallium nitride GaN), called III-V compound hereafter, or mainly comprising at least one group-II element and one group-VI element (for example, zinc oxide ZnO), called II-VI compound hereafter. Such devices are for example described in French patent applications FR 2995729 and FR 2997558.

It is known to form an active area comprising confinement means, in particular a single quantum well or multiple quantum wells. A single quantum well is formed by interposing, between two layers of a first semiconductor material, for example, a III-V compound, particularly GaN, respectively P- and N-type doped, a layer of a second semiconductor material, for example, an alloy of the III-V compound and of a third element, particularly, InGaN, having a different bandgap than the first semiconductor material. A multiple quantum well structure comprises a stack of semiconductor layers forming an alternation of quantum wells and of barrier layers.

The wavelength of the electromagnetic radiation emitted by the active area of the optoelectronic device particularly depends on the bandgap of the second material forming the quantum well. When the second material is an alloy of the III-V compound and of a third element, for example, InGaN, the wavelength of the emitted radiation particularly depends on the atomic percentage of the third element, for example, indium. In particular, the higher the atomic percentage of indium, the higher the wavelength.

A disadvantage is that when the atomic percentage of indium exceeds a threshold, differences in lattice parameters can be observed between the GaN and InGaN of the quantum well, which may cause the forming of non-radiative defects in the active layer, such as dislocations, which causes a significant decrease in the quantum efficiency of the active area of the optoelectronic device. There thus is a maximum wavelength of the radiation emitted by an optoelectronic device having its active area comprising a single quantum well or multiple quantum wells based on III-V or II-VI compounds. In particular, the forming of light-emitting diodes made of III-V or II-VI compounds emitting in red may be difficult.

However, the use of materials made from III-V or II-VI compounds is desirable since there exist methods of growing such materials by epitaxy on substrates of large dimensions and at a low cost.

It is known to cover a light-emitting diode with a photoluminescent material capable of converting the electromagnetic radiation emitted by the active area into an electromagnetic radiation at a different wavelength, particularly, higher. However, such photoluminescent materials may have a high cost, have a low conversion efficiency, and have a performance which degrades over time.

Further, it may be difficult to form an axial-type three-dimensional light-emitting diode based on III-V or II-VI compounds with an active area having an emission spectrum having the desired properties, in particular comprising a narrow band around the target emission frequency.

Further, the industrial development of the method of manufacturing an active area of an axial-type three-dimensional light-emitting diode based on III-V or II-VI compounds is a touchy operation. It would thus be desirable to simultaneously form all the active areas of the light-emitting diodes of an optoelectronic device with the same structure and the same composition and to be able to subsequently modify the emission spectrum of groups of light-emitting diodes without using photoluminescent materials.

### SUMMARY

Thus, an object of an embodiment aims at overcoming all or part of the disadvantages of the previously-described optoelectronic devices comprising light-emitting diodes.

Another object of an embodiment is for the active area of each light-emitting diode to comprise a stack of semiconductor materials based on III-V or II-VI compounds.

Another object of an embodiment is for the optoelectronic device to comprise light-emitting diodes configured to emit a light radiation in red without using photoluminescent materials.

Another object of an embodiment is for the axial-type three-dimensional light-emitting diodes based on III-V or II-VI compounds with an active area having an emission spectrum having the desired properties, in particular comprising a narrow band around the target emission frequency.

Another object of an embodiment is to be able to modify the emission frequency of light-emitting diodes after the forming of the active areas of the light-emitting diodes without using photoluminescent materials.

An embodiment provides an optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to be able to form three resonance peaks amplifying the intensity of said electromagnetic radiation at at least second, third, and fourth wavelengths.

According to an embodiment, each active area is configured to emit the electromagnetic radiation having an emission spectrum with a full width at half maximum in the range from 100 nm to 180 nm.

According to an embodiment, the photonic crystal is a two-dimensional photonic crystal.

According to an embodiment, the light-emitting diodes are arranged in an array with a pitch in the range from 400 nm to 475 nm and each light-emitting diode is cylindrical with an average diameter in the range from 270 nm to 300 nm.

According to an embodiment, the light-emitting diodes are based on a III-V or II-VI compound.

According to an embodiment, the light-emitting diodes are separated by an electrically-insulating material having a refraction index in the range from 1.3 to 1.6, preferably from 1.45 to 1.56.

According to an embodiment, one of the second, third, and fourth wavelengths is in the range from 430 nm to 480 nm, another one of the second, third, and fourth wavelengths being in the range from 510 nm to 570 nm, and still another one of the second, third, and fourth wavelengths being in the range from 600 nm to 720 nm.

According to an embodiment, the emission spectrum of the active area has energy at the second wavelength.

According to an embodiment, the device further comprises a first optical filter covering at least a first portion of said array of light-emitting diodes, the first optical filter being configured to block said amplified radiation over a first wavelength range comprising the first, third, and fourth wavelengths and to give way to said amplified radiation over a second wavelength range comprising the second wavelength.

According to an embodiment, the emission spectrum of the active area has energy at the third wavelength.

According to an embodiment, the device further comprises a second optical filter covering at least a second portion of said array of light-emitting diodes, the second optical filter being configured to block said amplified radiation over a third wavelength range comprising the first, second, and fourth wavelengths and to give way to said amplified radiation over a fourth wavelength range comprising the third wavelength.

According to an embodiment, the emission spectrum of the active area has energy at the fourth wavelength.

According to an embodiment, the device further comprises a third optical filter covering at least a third portion of said array of light-emitting diodes, the third optical filter being configured to block said amplified radiation over a fifth wavelength range comprising the first, second, and third wavelengths and to give way to said amplified radiation over a sixth wavelength range comprising the fourth wavelength.

According to an embodiment, the device comprises a support having the light-emitting diodes resting thereon, each light-emitting diode comprising a stack of a first semiconductor portion resting on the support, of the active area in contact with the first semiconductor portion, and of a second semiconductor portion in contact with the active area.

According to an embodiment, the second semiconductor portions of the light-emitting diodes are covered with an electrically-conductive layer at least partly transparent to the radiation emitted by the light-emitting diodes.

According to an embodiment, at least one of the resonance peaks is attenuated with respect to the other resonance peaks.

According to an embodiment, the lateral walls of the first and second semiconductor portions of at least part of the light-emitting diodes are covered with a sheath.

According to an embodiment, a first portion of the electrically-conductive layer covering a first group of said light-emitting diodes has a first thickness and a second portion of electrically-conductive layer covering a second group of said light-emitting diodes has a second thickness, smaller than the first thickness.

According to an embodiment, the light-emitting diodes of a first group of said light-emitting diodes are separated by a first electrically-insulating material having a first refraction index and the light-emitting diodes of a second group of said light-emitting diodes are separated by a second electrically-insulating material having a second refraction index different from the first refraction index.

An embodiment also provides a method of manufacturing optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to form three resonance peaks amplifying the intensity of said electromagnetic radiation at at least second, third, and fourth wavelengths.

According to an embodiment, the forming of the light-emitting diodes of the array comprises the steps of:
forming second semiconductor portions on a substrate, the second semiconductor portions being separated from one another by the pitch of the array;
forming an active area on each second semiconductor portion; and
forming a first semiconductor portion on each active area.

According to an embodiment, the light-emitting diodes are distributed in at last first and second groups of light-emitting diodes. The method comprises forming a first optical filter on the first group and a second optical filter on the second group, the second optical filter being different from the first optical filter.

According to an embodiment, the method comprises attenuating at least one of the resonance peaks with respect to the other resonance peaks after the forming of the light-emitting diodes.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an optoelectronic device comprising light-emitting diodes;

FIG. 2 is a partial simplified perspective view of the optoelectronic device shown in FIG. 1;

FIG. 3 schematically shows an example of layout of the light-emitting diodes of the optoelectronic device shown in FIG. 1;

FIG. 4 schematically shows another example of a layout of the light-emitting diodes of the optoelectronic device shown in FIG. 1;

FIG. 5 schematically shows curves of the variation of light intensities of the radiation emitted by the optoelectronic device of FIG. 1 illustrating a configuration with three resonances;

FIG. 6 illustrates a method of selection of a resonance of the radiation in a configuration with three resonances;

FIG. 7 illustrates a method of selection of another resonance of the radiation in a configuration with three resonances;

FIG. 8 illustrates a method of selection of two resonances of the radiation in a configuration with three resonances;

FIG. 9 illustrates a method of selection of a resonance of the radiation in a configuration with three resonances;

FIG. 10 schematically shows curves of the variation of light intensities of the radiation emitted by an optoelectronic device illustrating a configuration with one resonance obtained from an initial configuration with three resonances;

FIG. 11 is a partial simplified cross-section view of an embodiment of an optoelectronic device having the emission spectrum of FIG. 10;

FIG. 12 is a partial simplified cross-section view of an embodiment of an optoelectronic device having the emission spectrum of FIG. 10;

FIG. 13 is a partial simplified cross-section view of an embodiment of an optoelectronic device having the emission spectrum of FIG. 10;

FIG. 14A illustrates a step of an embodiment of a method of manufacturing the optoelectronic device shown in FIG. 1;

FIG. 14B illustrates another step of the manufacturing method;

FIG. 14C illustrates another step of the manufacturing method;

FIG. 14D illustrates another step of the manufacturing method;

FIG. 14E illustrates another step of the manufacturing method;

FIG. 14F illustrates another step of the manufacturing method;

FIG. 14G illustrates another step of the manufacturing method;

FIG. 15 illustrates a step of another embodiment of a method of manufacturing the optoelectronic device shown in FIG. 1;

FIG. 16 is a grayscale map of the light intensity emitted at a first wavelength by a light-emitting diode of a photonic crystal of the optoelectronic device according to the pitch of the photonic crystal and to the diameter of the light-emitting diode;

FIG. 17 is a grayscale map of the light intensity emitted at a second wavelength by a light-emitting diode of a photonic crystal of the optoelectronic device according to the pitch of the photonic crystal and to the diameter of the light-emitting diode;

FIG. 18 is a grayscale map of the light intensity emitted at a third wavelength by a light-emitting diode of a photonic crystal of the optoelectronic device according to the pitch of the photonic crystal and to the diameter of the light-emitting diode; and

FIG. 19 shows a curve of the variation of the light intensity of the light-emitting diodes according to the wavelength measuring during a test.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the considered optoelectronic devices optionally comprise other components, which will not be detailed.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use.

Unless specified otherwise, the expressions “around”, “approximately”, “substantially” and “in the order of” signify within 10%, and preferably within 5%. Further, it is here considered that the terms “insulating” and “conductive” respectively mean “electrically insulating” and “electrically conductive”.

In the following description, the inner transmittance of a layer corresponds to the ratio of the intensity of the radiation coming out of the layer to the intensity of the radiation entering in the layer. The absorption of the layer is equal to the difference between 1 and the inner transmittance. In the following description, a layer is said to be transparent to a radiation when the absorption of the radiation through the layer is smaller than 60%. In the following description, a layer is said to be absorbing for a radiation when the absorption of the radiation in the layer is higher than 60%. When a radiation exhibits a generally “bell”-shaped spectrum, for example, of Gaussian shape, having a maximum, the expression wavelength of the radiation, or central or main wavelength of the radiation, designates the wavelength at which the maximum of the spectrum is reached. In the following description, the refraction index of a material corresponds to the refraction index of the material for the wavelength range of the radiation emitted by the optoelectronic device. Unless specified otherwise, the refraction index is considered as substantially constant over the wavelength range of the useful radiation, for example, equal to the average of the refraction index over the wavelength range of the radiation emitted by the optoelectronic device.

Further, “compound mainly formed of a material” or “compound based on a material” means that a compound comprises a proportion greater than or equal to 95% of said material, this proportion being preferably greater than 99%. The term axial light-emitting diode designates a three-dimensional structure having an elongated shape, for example, cylindrical, along a main direction having at least two dimensions, called minor dimensions, in the range from 5 nm to 2.5 μm, preferably from 50 nm to 2.5 μm. The third dimension, called major dimension, is greater than or equal to 1 time, preferably greater than or equal to 5 times, and more preferably greater than or equal to 10 times the largest minor dimension. In certain embodiments, the minor dimensions may be smaller than or equal to approximately 1 μm, preferably in the range from 100 nm to 1 μm, more preferably from 100 nm to 800 nm. In certain embodiments, the height of each light-emitting diode may be greater than or equal to 500 nm, preferably in the range from 1 μm to 50 μm. The diameter of the wire of circular base having the same surface area as the surface area of the base of the considered wire is called average diameter of the wire.

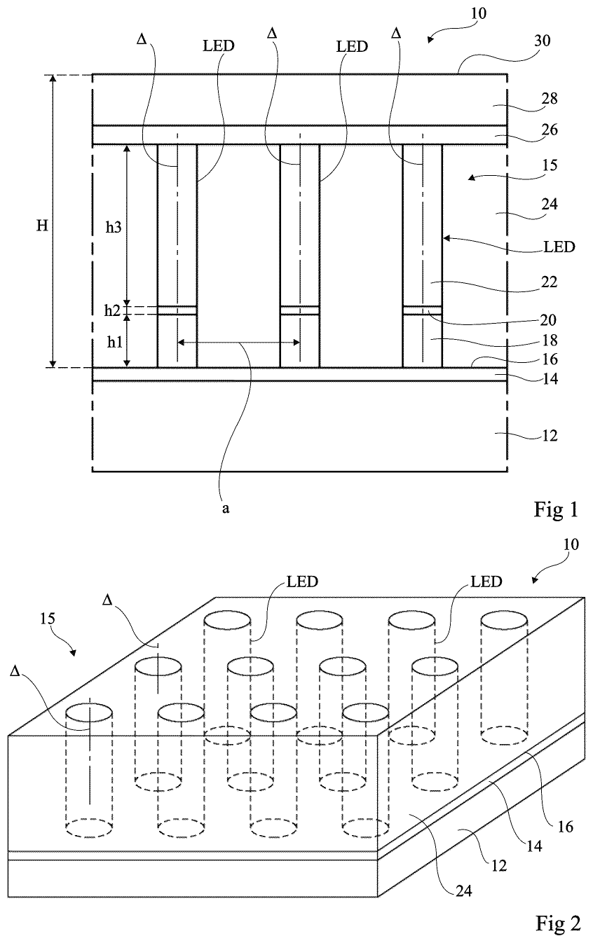

FIGS. 1 and 2 respectively are a lateral cross-section view and a perspective view, partial and simplified, of an embodiment of an optoelectronic device 10 comprising light-emitting diodes.

Optoelectronic device 10 comprises, from bottom to top in FIG. 1:
a support 12;
a first electrode layer 14 resting on support 12 and having an upper surface 16;
an array 15 of axial light-emitting diodes LED resting on surface 16, each axial light-emitting diode comprising, from bottom to top in FIG. 1, a lower semiconductor portion 18, not shown in FIG. 2, in contact with electrode layer 14, an active area 20, not shown in FIG. 2, in contact with semiconductor portion 18, and an upper semiconductor portion 22, not shown in FIG. 2, in contact with active area 20;
an insulating layer 24 extending between light-emitting diodes LED, all along the height of light-emitting diodes LED;
a second electrode layer 26, not shown in FIG. 2, covering light-emitting diodes LED in contact with the upper portions 22 of light-emitting diodes LED; and
a coating 28, not shown in FIG. 2, covering second electrode layer 26, and delimiting an emission surface 30 of optoelectronic device 10.

Each light-emitting diode LED is called axial since active area 20 is in line with lower portion 18 and upper portion 22 is in line with active area 20, the assembly comprising lower portion 18, active area 20, and upper portion 22 extending along an axis Δ, called axis of the axial light-emitting diode. Preferably, the axes A of light-emitting diodes LED are parallel and orthogonal to surface 16.

Support 12 may correspond to an electronic circuit. Electrode layer 14 may be metallic, for example, made of silver, of copper, or of zinc. The thickness of electrode layer 14 is sufficient for electrode layer 14 to form a mirror. As an example, electrode layer 14 has a thickness greater than 100 nm. Electrode layer 14 may totally cover support 12. As a variant, electrode layer 14 may be divided into distinct portions to allow the separate control of groups of light-emitting diodes of the array of light-emitting diodes. According to an embodiment, surface 16 may be reflective. Electrode layer 14 may then have a specular reflection. According to another embodiment, electrode layer 14 may have a lambertian reflection. To obtain a surface having a lambertian reflection, a possibility is to create unevennesses on a conductive surface. As an example, when surface 16 corresponds to the surface of a conductive layer resting on a base, a texturing of the surface of the base may be performed before the deposition of the metal layer so that surface 16 of the metal layer, once deposited, exhibits raised areas.

Second electrode layer 26 is conductive and transparent. According to an embodiment, electrode layer 26 is a transparent conductive oxide (TCO) layer, such as indium-tin oxide (ITO), zinc oxide doped or not with aluminum, or with gallium, or graphene. As an example, electrode layer 26 has a thickness in the range from 5 nm to 200 nm, preferably from 20 nm to 50 nm. Insulating layer 24 may be made of an inorganic material, for example, of silicon oxide or of silicon nitride. Insulating layer 24 may be made of an organic material, for example, an insulating polymer based on benzocyclobutene (BCB). Coating 28 may comprise an optical filter, or optical filters arranged next to one another, as will be described in further detail hereafter. According to an embodiment, the refraction index of the material of insulating layer 24 is in the range from 1.3 to 1.6, preferably from 1.45 to 1.56.

In the embodiment shown in FIGS. 1 and 2, all light-emitting diodes LED have the same height. The thickness of insulating layer 24 is for example selected to be equal to the height of light-emitting diodes LED so that the upper surface of insulating layer 24 is coplanar with the upper surfaces of the light-emitting diodes.

According to an embodiment, semiconductor portions 18 and 22 and active areas 20 are at least partly made of a semiconductor material. The semiconductor material is selected from the group comprising III-V compounds, II-VI compounds, and group-IV semiconductors or compounds. Examples of group-III elements comprise gallium (Ga), indium (In), or aluminum (Al). Examples of group-IV elements comprise nitrogen (N), phosphorus (P), or arsenic (As). Examples of III-N compounds are GaN, AN, InN, InGaN, AlGaN, or AlInGaN. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (O) and tellurium (Te). Examples of II-VI compounds are ZnO, ZnMgO, CdZnO, CdZnMgO, CdHgTe, CdTe, or HgTe. Generally, the elements in the III-V or II-VI compound may be combined with different molar fractions. Examples of group-IV semiconductor materials are silicon (Si), carbon (C), germanium (Ge), silicon carbide alloys (SiC), silicon-germanium alloys (SiGe), or germanium carbide alloys (GeC). Semiconductor portions 18 and 22 may comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C), or an N-type group-IV dopant, for example, silicon (Si), germanium (Ge), selenium (Se), sulfur (S), terbium (Tb), or tin (Sn). Preferably, semiconductor portion 18 is made of P-doped GaN and semiconductor portion 22 is made of N-doped GaN.

For each light-emitting diode LED, active area 20 may comprise confinement means. As an example, active area 20 may comprise a single quantum well. It then comprises a semiconductor material different from the semiconductor material forming semiconductor portions 18 and 22 and having a bandgap smaller than that of the material forming semiconductor portions 18 and 22. Active area 20 may comprise multiple quantum wells. It then comprises a stack of semiconductor layers forming an alternation of quantum wells and of barrier layers.

In FIGS. 1 and 2, each light-emitting diode LED has the shape of a cylinder with a circular base of axis Δ. However, each light-emitting diode LED may have the shape of a cylinder of axis Δ with a polygonal base, for example, square, rectangular, or hexagonal. Preferably, each light-emitting diode LED has the shape of a cylinder with a hexagonal base.

Call height H of light-emitting diode LED the sum of the height h1 of lower portion 18, of the height h2 of active area 20, of the height h3 of upper portion 22, of the thickness of electrode layer 26, and of the thickness of coating 28.

According to an embodiment, light-emitting diodes LED are arranged to form a photonic crystal. Twelve light-emitting diodes LED are shown as an example in FIG. 2. In practice, array 15 may comprise from 7 to 100,000 light-emitting diodes LED.

The light-emitting diodes LED of array 15 are arranged in rows and in columns (3 rows and 4 columns being shown as an example in FIG. 2). The pitch ‘a’ of array 15 is the distance between the axis of a light-emitting diode LED and the axis of a close light-emitting diode LED, in the same row or in an adjacent row. Pitch a is substantially constant. More particularly, pitch a of the array is selected so that array 15 forms a photonic crystal. The formed photonic crystal is for example, a 2D photonic crystal.

The properties of the photonic crystal formed by array 15 are advantageously selected so that array 15 of light-emitting diodes forms a resonant cavity in the plane perpendicular to axis Δ and a resonant cavity along axis Δ, particularly to obtain a coupling and increase the selection effect. This enables the intensity of the radiation emitted by the assembly of light-emitting diodes LED of array 15 through emission surface 30 to be amplified for certain wavelengths with respect to an assembly of light-emitting diodes LED which would not form a photonic crystal.

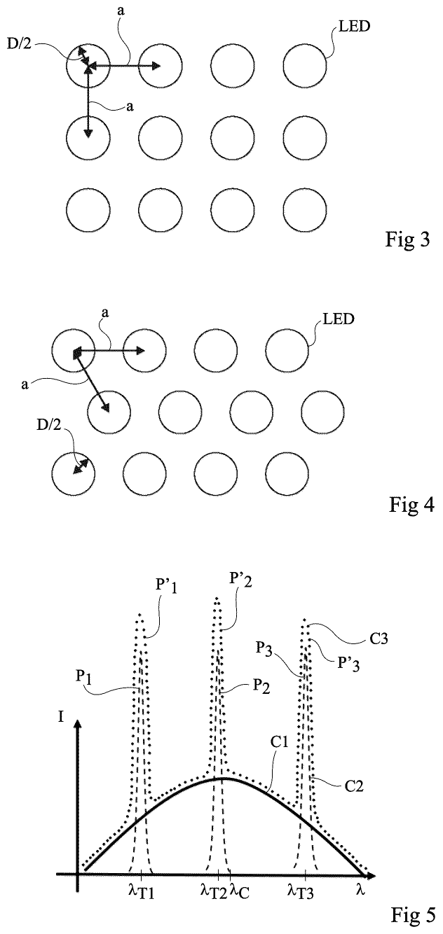

FIGS. 3 and 4 schematically show examples of layouts of the light-emitting diodes LED of array 15. In particular, FIG. 3 illustrates a so-called square lattice layout and FIG. 4 illustrates a so-called hexagonal lattice layout. FIGS. 3 and 4 each show three rows of four light-emitting diodes LED. In the layout illustrated in FIG. 3, a light-emitting diode LED is located at each intersection of a row and of a column, the rows being perpendicular to the columns. In the layout illustrated in FIG. 4, the diodes on a row are shifted by half of pitch a with respect to the light-emitting diodes on the previous row and the next row.

In the embodiments illustrated in FIGS. 3 and 4, each light-emitting diode LED has a circular cross-section of diameter D in a plane parallel to surface 16. In the case of a hexagonal lattice layout or a square lattice layout, diameter D may be in the range from 0.05 μm to 2 μm. Pitch a may be in the range from 0.1 μm to 4 μm.

Further, according to an embodiment, the height H of light-emitting diode LED is selected so that each light-emitting diode LED forms a resonant cavity along axis Δ at the desired central wavelength λ of the radiation emitted by optoelectronic device 10. According to an embodiment height H is selected to be substantially proportional to k*(λ/2)*neff, neff being the effective refraction index of the light-emitting diode in the considered optical mode, and k being a positive integer. The effective refraction index is for example defined in work “Semiconductor Optoelectronic Devices: Introduction to Physics and Simulation” of Joachim Piprek.

In the case where the light-emitting diodes are distributed in groups of light-emitting diodes emitting at different central wavelengths, height H may however be the same for all light-emitting diodes. It may then be determined from the theoretical heights which would enable to obtain resonant cavities for the light-emitting diodes of each group, and is for example equal to the average of the theoretical heights.

According to an embodiment, the properties of the photonic crystal, formed by the array 15 of light-emitting diodes LED, are selected to increase the light intensity emitted by array 15 of light-emitting diodes LED at at least three target wavelengths. According to an embodiment, the active area 20 of each light-emitting diode LED has a relatively spread emission spectrum, particularly having a maximum at a first wavelength and a full width at half maximum greater than 100 nm, preferably greater than 180 nm, so as to cover the three target wavelengths, that is, the energy of the emission spectrum of active area 20 at the target wavelengths is not null. According to an embodiment, the maximum of the spectrum of the radiation emitted by active area 20 is at a wavelength different from at least two of the target wavelengths.

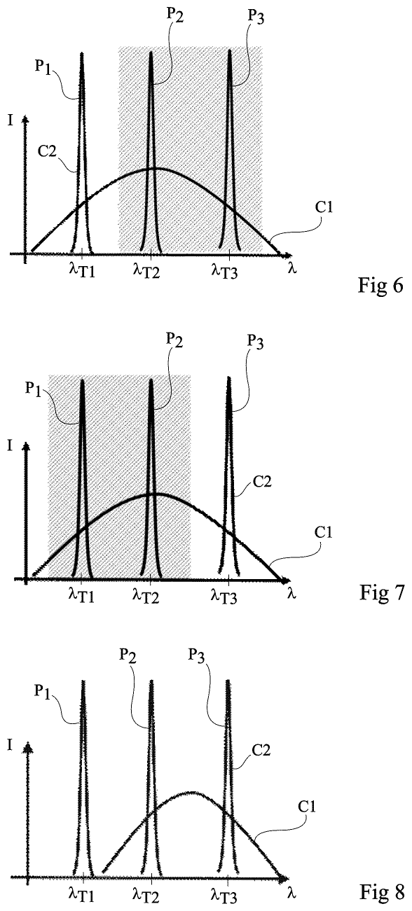

FIG. 5 schematically shows, according to wavelength λ, a curve C1 of the variation (in full line) of the light intensity I emitted by the active areas 20 of light-emitting diodes LED considered separately, a curve C2 of the variation (in dashed lines in FIG. 5 and in full lines in FIGS. 6 to 10) of the amplification factor due to the coupling with the photonic crystal, and a curve C3 of the variation (in dotted lines) of the light intensity emitted by array 15 of light-emitting diodes. Curve C1 has a general “bell” shape and has a top at a central wavelength λ_{C}. Curve C2 comprises three narrow resonance peaks, a first resonance peak P₁ centered on target wavelength λ_{T1}, a second resonance peak P₂ centered on target wavelength λ_{T2}, and a third resonance peak P₃ centered on target wavelength λ_{T3}. Curve C3 comprises an intensity peak P′₁ at target wavelength λ_{T1}, an intensity peak P′₂ at target wavelength λ_{T2}, an intensity peak P′₃ at target wavelength λ_{T3}, and substantially follows curve C1 for the other wavelengths. In particular, the full width at half maximum of curve C1 for top S is greater than the full width at half maximum of curve C3 for each peak P′₁, P′₂, and P′₃, for example, by a factor 2, in particular by a factor 10.

According to an embodiment, target wavelength 41 corresponds to blue light, that is, a radiation having a wavelength in the range from 430 nm to 480 nm. According to an embodiment, target wavelength λ_{T2} corresponds to green light, that is, a radiation having a wavelength in the range from 510 nm to 570 nm. According to an embodiment, target wavelength λ_{T3} corresponds to red light, that is, a radiation having a wavelength in the range from 600 nm to 720 nm.

According to an embodiment, an optoelectronic device 10 emitting a narrow-spectrum light radiation at one of target wavelengths λ_{T1}, λ_{T2}, or λ_{T3} may be obtained by filtering of the radiation emitted by array 15 of light-emitting diodes LED to only keep the intensity peak at the desired target wavelength. This may be obtained by providing an optical filter in coating 28.

FIGS. 6 and 7 illustrate the principle of filtering of the radiation emitted by array 15 of light-emitting diodes. An optoelectronic device emitting a narrow-spectrum light radiation centered on a target wavelength may be obtained by blocking the unwanted portion of the emission spectrum of array 15 of light-emitting diodes. A an example, in FIGS. 6 and 7, the blocked portion of the spectrum of the radiation emitted by array 15 of light-emitting diodes is hatched and only one of the resonance peaks is kept, resonance peak P₁ at target wavelength λ_{T1} in FIG. 6 and resonance peak P₃ at target wavelength λ_{T3} in FIG. 7.

The height h1 of lower portion 18 and the height h2 of upper portion 22 may advantageously be determined so that the light intensity of the peak at the target wavelength is maximum.

The filtering of the radiation emitted by the array of light-emitting diodes may be performed by any means. According to an embodiment, the filtering is obtained by covering the light-emitting diodes with a layer of a colored material. According to another embodiment, the filtering is obtained by covering the light-emitting diodes with an interference filter.

According to an embodiment, the light-emitting diodes of the array of light-emitting diodes may be distributed in first and second groups of light-emitting diodes. A first filtering is implemented for the light-emitting diodes of the first group to only keep a first resonance peak and a second filtering is implemented for the light-emitting diodes of the second group to only keep a second resonance peak. An optoelectronic device configured for the emission of a first radiation at a first target wavelength and of a second radiation at a second target wavelength may thus be obtained while the active areas of the light-emitting diodes and the arrays of light-emitting diodes of the first and second groups have the same structure.

According to an embodiment, the light-emitting diodes may be distributed in first, second, and third groups of light-emitting diodes. A first filtering is implemented for the light-emitting diodes of the first group to only keep a first resonance peak. A second filtering is implemented for the light-emitting diodes of the second group to only keep a second resonance peak. A third filtering is implemented for the light-emitting diodes of the third group to only keep a third resonance peak. An optoelectronic device configured for the emission of a first radiation at a first target wavelength, of a second radiation at a second target wavelength, and of a third radiation at a third target wavelength can thus be obtained while the active areas of the light-emitting diodes and the arrays of light-emitting diodes of the first, second, and third groups have the same structure. This particularly enables to form display sub-pixels for a display pixel of a color image display screen.

According to an embodiment, the radiation after filtering of the first group of light-emitting diodes corresponds to blue light, that is, a radiation having a wavelength in the range from 430 nm to 480 nm. According to an embodiment, the radiation after filtering of the second group of light-emitting diodes corresponds to green light, that is, to a radiation having a wavelength in the range from 510 nm to 570 nm. According to an embodiment, the radiation after filtering of the third group of light-emitting diodes corresponds to red light, that is, a radiation having a wavelength in the range from 600 nm to 720 nm.

Advantageously, active areas 20 having the same structure and the same composition may be used to manufacture optoelectronic devices capable of emitting narrow-spectrum radiations at different target wavelengths. This enables to do away, on design of a new optoelectronic device, with the designing of a new structure for the active areas, with all the industrial development issues that this implies, and thus to simplify the method of designing a new optoelectronic device. Indeed, all the light-emitting diodes may be formed with the same structure, so that the initial steps of the manufacturing method at least until the manufacturing of the light-emitting diodes may be common for the manufacturing of different optoelectronic devices.

It may further be advantageous for active area 20 to emit a radiation of maximum intensity at a central wavelength λ_{C} different from target wavelengths λ_{T1}, λ_{T2}, or λ_{T3}, or at least from two of them. Indeed, as an example, when active area 20 comprises an InGaN layer, the central wavelength of the emitted radiation increases with the proportion of indium. However, to obtain an emission wavelength corresponding to red, a proportion of indium greater than 16% should be obtained, which translates as a drop in the quantum efficiency of the active area. The fact of using an active area 20 emitting a radiation of maximum intensity at a central wavelength λ_{C} smaller than target wavelength λ_{T1} then enables to use an active area 20 with an improved quantum efficiency. This further enables to obtain a radiation at target wavelength λ_{T1} by using an active area 20, emitting a radiation of maximum intensity at central wavelength λ_{C}, which is more to manufacture, without having to use photoluminescent materials.

An active area 20 emitting a radiation having a spectrum with a larger spread than the desired spectrum for the radiation emitted by the optoelectronic device may further be used. This may simplify the design and the manufacturing of active area 20.

According to another embodiment, the selection of the target wavelength of the radiation emitted by the optoelectronic device may be obtained by using an active area having an emission spectrum which, although it is spread, does not cover the three target wavelengths λ_{T1}, λ_{T2}, and λ_{T3}. Only one intensity peak or intensity peaks are then obtained in the radiation emitted by array 15 of light-emitting diodes for the target wavelengths λ_{T1}, λ_{T2}, or λ_{T3} which are in the band of the radiation emitted by active areas 20.

FIG. 8 is a drawing similar to FIG. 5, with the difference that curve C1 of variation of the spectrum emitted by active areas 20 only covers two narrow resonance peaks of curve C2 respectively centered on target wavelengths λ_{T2} and λ_{T3}. The corresponding curve C3 (not shown) then comprises top S at central wavelength λ_{C}, an intensity peak at target wavelength λ_{T2}, and an intensity peak at target wavelength λ_{T3}.

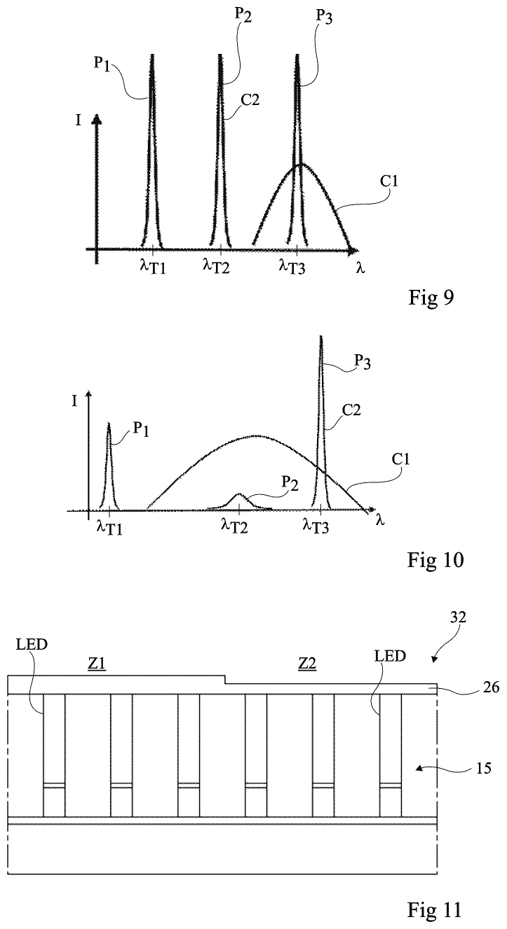

FIG. 9 is a drawing similar to FIG. 5, with the difference that curve C1 of variation of the spectrum emitted by active areas 20 only covers a single narrow resonance peak of curve C2 respectively centered on target wavelength λ_{T3}. The corresponding curve C3 (not shown) then comprises top S at central wavelength λ_{C}, and an intensity peak at target wavelength λ_{T3}.

More generally, the epitaxial conditions for the growth of the active areas 20 can be selected so that the spectrum emitted by active areas 20 covers alternatively only wavelength λ_{T1}, λ_{T2}, or λ_{T3} without modifying the photonic crystal. This can be achieved for example by modifying only the Indium concentration in the active area 20 when the active areas 20 comprise InGaN quantum wells. This allows advantageously the industrially manufacture of devices emitting at three different target wavelengths with mostly identical base manufacturing parameters except for the growth of the active areas 20.

According to another embodiment, the selection of the target wavelength of the radiation emitted by the optoelectronic device may be obtained by modifying the properties of the photonic crystal with respect to the reference structure previously described in relation with FIGS. 1 and 2 and which causes the presence of the three resonance peaks, to decrease the amplitude of one of the resonance peaks, preferably to annul one of the resonance peaks, or even to decrease the amplitude of two of the resonance peaks, preferably to annul two of the resonance peaks. Thereby, the spectrum of the radiation emitted by array 15 of light-emitting diodes comprises a smaller number of intensity peaks than what is obtained with the reference structure. According to an embodiment, the modification of the properties of the photonic crystal with respect to the reference structure is performed after the forming of array 15 of light-emitting diodes. A possibility is to introduce an element, particularly, a nanomaterial, around the wires to favor a resonance. Another possibility comprises modifying the material forming insulating layer 24 and/or coating 28. Another possibility comprises modifying the total height H of the structure, for example, by modifying the thickness of electrode layer 26. Thereby, all the light-emitting diodes may be formed with the same structure, so that the initial steps of the manufacturing method at least until the manufacturing of the light-emitting diodes may be common for the manufacturing of different optoelectronic components.

FIG. 10 is a drawing similar to FIG. 8, with the difference that the resonance peak P₂ of curve C2 of the variation of the amplification factor due to the photonic crystal at target wavelength λ_{T2} has substantially disappeared and that the amplitude of the resonance peak P₃ of variation curve C2 at target wavelength λ_{T3} is decreased. Thereby, the radiation emitted by array 15 of light-emitting diodes comprises a single intensity peak without for the use of an optical filter to be necessary.

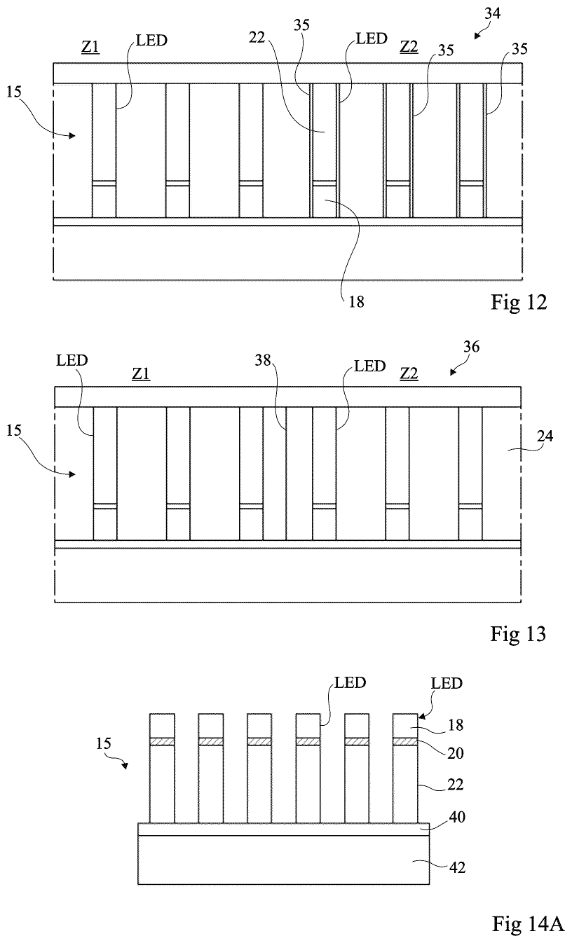

FIGS. 11, 12, and 13 are partial simplified cross-section views of embodiments of optoelectronic devices enabling to obtain the curves C1 and C2 shown in FIG. 10. Coating 28, possibly present, is not shown in FIGS. 11, 12, and 13. For each of the optoelectronic devices, the reference structure of the optoelectronic device 10 shown in FIG. 1 is kept in a first area Z1 to obtain a radiation in first area Z1 with three intensity peaks and the reference structure of the optoelectronic device 10 shown in FIG. 1 is modified in a second area Z2 to obtain a radiation in second area Z2 with fewer intensity peaks. In FIG. 11, the height H of light-emitting diodes LED is modified in second area Z2. In FIG. 12, the diameter of light-emitting diodes LED is modified in second area Z2. In FIG. 13, the refraction indexes of the materials forming the photonic sensor are modified in second area Z2.

FIG. 11 shows an optoelectronic device 32 comprising the assembly of elements of the optoelectronic device 10 shown in FIG. 1, with the difference that electrode layer 26 does not have a constant thickness. As an example, the thickness of electrode layer 26 in first area Z1 of the optoelectronic device 32 is thicker than the thickness of electrode layer 26 in second area Z2 of optoelectronic device 32. According to an embodiment, the thickness of electrode layer 26 in first area Z1 is that determined for the reference structure, which causes the presence of three intensity peaks in the radiation delivered by array 15 of light-emitting diodes LED in first area Z1. The decreased thickness of electrode layer 26 in second area Z2 causes a modification of the properties of the photonic crystal, so that the curves C1 and C2 shown in FIG. 10 are obtained for array 15 of light-emitting diodes LED in second area Z2.

FIG. 12 shows an optoelectronic device 34 comprising all the elements of the optoelectronic device 10 shown in FIG. 1 with the difference that a sheath 35 surrounds the lateral walls of each light-emitting diode LED in second area Z2. According to an embodiment, each sheath 35 is made of a material having a refraction index close to the refraction index of the material forming semiconductor portions 18 and 22. All then occurs as if the diameter of the light-emitting diodes was increased in second diode Z2 with respect to the diameter of the light-emitting diodes in first area Z1. The increased diameter in second area Z2 causes a modification of the properties of the photonic crystal, so that the curves C1 and C2 shown in FIG. 10 are obtained for array 15 of light-emitting diodes LED in second area Z2.

FIG. 13 shows an optoelectronic device 36 comprising all the elements of the optoelectronic device 10 shown in FIG. 1, with the difference that insulating layer 24 is, in second area Z2, made of a material having a different refraction index than first area Z2, which is illustrated by a limit 38 between the two areas Z1 and Z2. The modification of the refraction index of insulating layer 24 in second area Z2 causes a modification of the properties of the photonic crystal, so that the curves C1 and C2 shown in FIG. 10 are obtained for array 15 of light-emitting diodes LED in second area Z2.

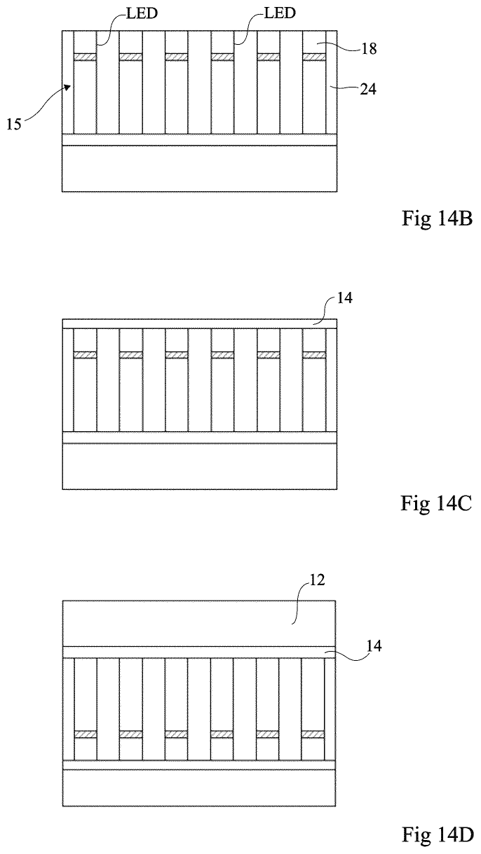

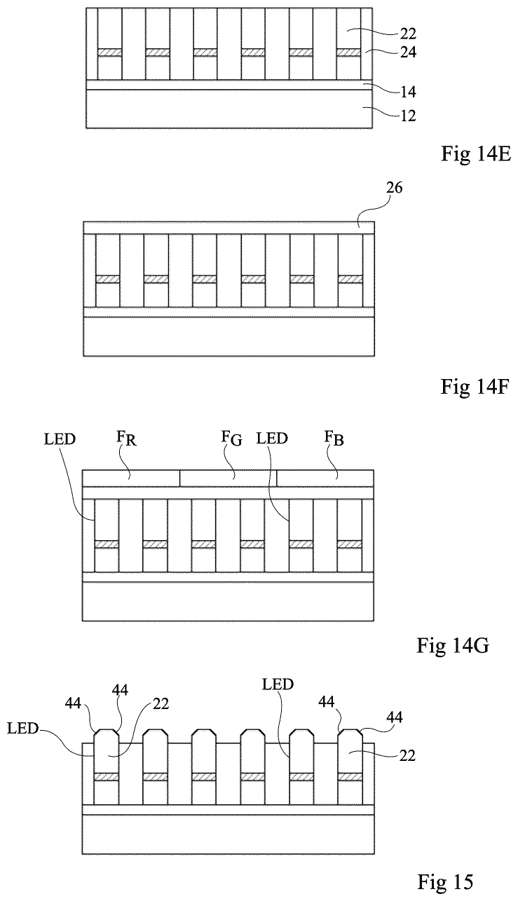

FIGS. 14A to 14G are partial simplified cross-section views of the structures obtained at successive steps of another embodiment of a method of manufacturing the optoelectronic device 10 shown in FIG. 1.

FIG. 14A illustrates the structure obtained after the forming steps described hereafter.

A seed layer 40 is formed on a substrate 42. Light-emitting diodes LED are then formed from seed layer 40. More particularly, light-emitting diodes LED are formed in such a way that upper portions 22 are in contact with seed layer 40. Seed layer 40 is made of a material which favors the growth of upper portions 22. For each light-emitting diode LED, active area 20 is formed on upper portion 22 and lower portion 18 is formed on active area 20.

Further, light-emitting diodes LED are located to form array 15, that is, to form rows and columns with the desired pitch of array 15. Only one row is partially shown in FIG. 14A to 14G.

A mask, not shown, may be formed before the forming of the light-emitting diodes on seed layer 40 to only expose the portions of seed layer 40 at the locations where the light-emitting diodes will be located. As a variant, seed layer 40 may be etched, before the forming of the light-emitting diodes, to form pads located at the locations where the light-emitting diodes will be formed.

The method of growing light-emitting diodes LED may be a method or a combination of methods such as chemical vapor deposition (CVD) or metal-organic chemical vapor deposition (MOCVD), also known as metal-organic vapor phase epitaxy (MOVPE). However, methods such as molecular-beam epitaxy (MBE), gas-source MBE (GSMBE), metal-organic MBE (MOMBE), plasma-assisted MBE (PAMBE), atomic layer epitaxy (ALE), or hydride vapor phase epitaxy (HVPE) may be used. However, electrochemical processes may be used, for example, chemical bath deposition (CBD), hydrothermal processes, liquid aerosol pyrolysis, or electrodeposition.

The conditions of growth of light-emitting diodes LED are such that all the light-emitting diodes of array 15 substantially form at the same speed. Thus, the heights of semiconductor portions 22 and 18 and the height of active area 20 are substantially identical for all the light-emitting diodes of array 15.

According to an embodiment, the height of semiconductor portion 22 is greater than the desired value h3. Indeed, it may be difficult to accurately control the height of upper portion 22, particularly due to the beginning of the growth of upper portion 22 from seed layer 40. Further, the forming of the semiconductor material directly on seed layer 40 may cause crystal defects in the semiconductor material just above seed layer 40. It may thus be desired to remove a portion of the upper portion 22 to obtain a constant height before the forming of active area 20.

FIG. 14B illustrates the structure obtained after the forming of layer 24 of the filling material, for example, an electrically-insulating material, for example, silicon oxide. Layer 24 is for example formed by depositing a layer of a filling material on the structure shown in FIG. 14A, the layer having a thickness greater than the height of light-emitting diodes LED. The layer of filling material is then partially removed to be planarized to expose the upper surfaces of semiconductor portions 18. The upper surface of layer 24 is then substantially coplanar with the upper surface of each semiconductor portion 18. As a variant, the method may comprise an etching step during which semiconductor portions 18 are partially etched.

The filling material is selected so that the photonic crystal formed by array 15 has the desired properties, that is, it selectively improves, in terms of wavelength, the intensity of the radiation emitted by the array of light-emitting diodes LED.

FIG. 14C illustrates the structure obtained after the deposition of electrode layer 14 on the structure obtained at the previous step.

FIG. 14D illustrates the structure obtained after the bonding to support 12 of layer 14, for example, by metal-to-metal bonding, by thermocompression, or by soldering with the use of eutectics on the side of support 12.

FIG. 14E illustrates the structure obtained after the removal of substrate 42 and of seed layer 40. Further, layer 24 and upper portions 22 are etched so that the height of each upper portion 22 has the desired value h3. This step advantageously enables to exactly control height h of the light-emitting diodes and to remove the portions of upper portions 22 which may have crystal defects.

FIG. 14F illustrates the structure obtained after the deposition of electrode layer 26.

FIG. 14G illustrates the structure obtained after the forming of at least optical filter over all or part of the structure shown in FIG. 14E. As an example, first, second, and third optical filters F_{R}, F_{G}, F_{B}, respectively placed on first, second, and third groups of light-emitting diodes LED have been shown.

FIG. 15 illustrates a variant of the method of manufacturing the optoelectronic device shown in FIG. 1, where a step of partial etching of the free end of each upper portion 22 of light-emitting diodes LED is implemented before the forming of electrode layer 26. The partial etch step may comprise the forming of inclined sides 44 at the free end of upper portions 22. This enables to slightly modify the properties of the photonic crystal. This thus enables to more finely modify the position of the resonance peaks of the amplification due to the photonic crystal.

Simulations and a test have been carried out. For the simulations and for the test, for each light-emitting diode LED, lower semiconductor portion 18 was made of P-type doped GaN. Upper semiconductor portion 22 was made of N-type doped GaN. The refraction index of lower and upper portions 18 and 22 was approximately 2.4. Active area 20 corresponded to an InGaN layer. The height h2 of active area 20 was equal to 40 nm. Electrode layer 14 was made of aluminum. Insulating layer 24 was made of a BCB polymer. The refraction index of insulating layer 24 was in the range from 1.45 to 1.56. For the simulations, a specular reflection on surface 16 has been considered. The height of portions 18 and 22 is not a determining parameter since this does not substantially modify the position of the resonance peaks, even if this has an impact on the intensity of the resonance peaks.

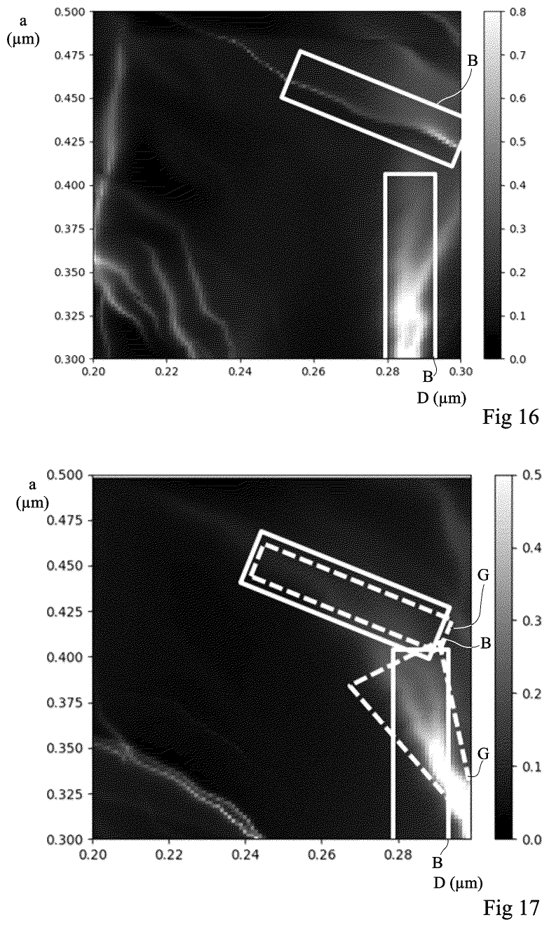

FIGS. 16, 17, and 18 are grayscale maps of the light intensity of the radiation emitted in a first direction inclined by 5 degrees with respect to a direction orthogonal to emission surface 30 respectively at a first, second, and third wavelength of array 15 of light-emitting diodes LED according to the pitch ‘a’ of the photonic crystal and to the diameter ‘D’ of each light-emitting diode. For the simulations, the first wavelength was 450 nm (color blue), the second wavelength was 530 nm (color green), and the third wavelength was 630 nm (color red).

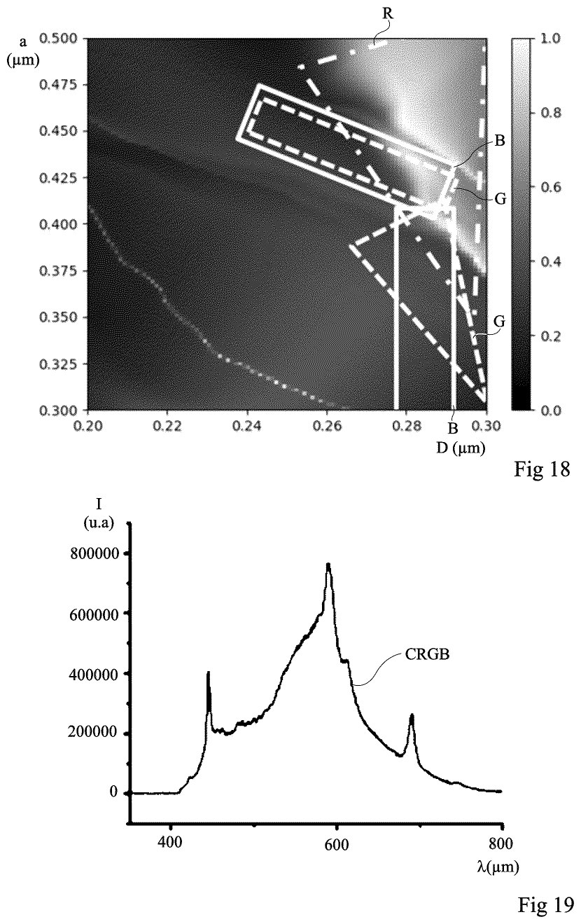

Each of the grayscale maps comprises lighter areas which correspond to resonance peaks. Such areas with resonance peaks are schematically indicated by contours B in full line in FIG. 16, by contours G in dotted lines in FIG. 17 and by contours R in stripe-dot lines in FIG. 18.

This thus means, as an example, that by selecting the pitch ‘a’ of the photonic crystal and the diameter ‘D’ of the light-emitting diodes to be located in one of the regions delimited by contours B in FIG. 16, the emission spectrum of array 15 of light-emitting diodes LED, obtained with no filtering, has at least one resonance peak at the 450-nm wavelength.

In FIG. 17, the contours B of FIG. 16 have been superposed to contours G. This thus means, as an example, that by the selection the pitch ‘a’ of the photonic crystal and the diameter ‘D’ of the light-emitting diodes to be located in one of the regions delimited both by contours B and G in FIG. 17, the emission spectrum of array 15 of light-emitting diodes LED, obtained with no filtering, has at least one resonance peak at the 450-nm wavelength and one resonance peak at the 530-nm wavelength.

In FIG. 18, the contours B of FIG. 16 and the contours G of FIG. 17 have been superposed to contours R. This thus means, as an example, that by the selection of the pitch ‘a’ of the photonic crystal and the diameter ‘D’ of the light-emitting diodes in order to be in one of the regions delimited both by contours B, G, and R in FIG. 18, the emission spectrum of array 15 of light-emitting diodes LED, obtained with no filtering, has at least one resonance peak at the 450-nm wavelength, a resonance peak at the 530-nm wavelength, and a resonance peak at the 630-nm wavelength. The three peaks are obtained with a height H equal to approximately 1 μm, a pitch ‘a’ of the photonic crystal equal to 400 nm, and the diameter of the circle circumscribed within the hexagonal base of the light-emitting diodes varying between 260 nm and 270 nm+/−25 nm, which corresponds to a corrected diameter varying between 280 nm and 290 nm.

It should be noted that an optimization may be performed by varying heights h1 and h3.

For the test, the light-emitting diodes had a hexagonal base. Approximately, it has been considered that the simulations performed for light-emitting diodes with a circular base having a given radius are equivalent to simulations for which the light-emitting diodes would have a hexagonal base, with a circle circumscribed within the hexagonal cross-section having a radius equal to 1.1 time the given radius. Semiconductor portions 18 and 22 and the active layers 20 of all the photodiodes have been simultaneously formed by MOCVD.

The test has been performed with the previously-described dimensions.

FIG. 19 shows a curve of the variation CRGB of the light intensity I, in arbitrary units, of array 15 of light-emitting diodes according to the wavelength for the test. Three resonance peaks are effectively obtained at the 450-nm, 590-nm, and 700-nm wavelengths.

Various embodiments and variants have been described. Those skilled in the art will understand that certain features of these embodiments can be combined and other variants will readily occur to those skilled in the art. In particular, the previously-described coating 28 may comprise additional layers other than an optical filter or optical filters. In particular, coating 28 may comprise an antireflection layer, a protection layer, etc. Finally, the practical implementation of the described embodiments and variants is within the abilities of those skilled in the art based on the functional indications given hereabove.

1. An optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to be able to form three resonance peaks amplifying the intensity of said electromagnetic radiation at at least second, third, and fourth wavelengths.

2. The device according to claim 1, wherein each active area is configured to emit the electromagnetic radiation having an emission spectrum with a full width at half maximum in the range from 100 nm to 180 nm.

3. The device according to claim 1, wherein the photonic crystal is a two-dimensional photonic crystal.

4. The device according to claim 1, wherein the light-emitting diodes are arranged in an array with a pitch in the range from 400 nm to 475 nm and wherein each light-emitting diode is cylindrical with an average diameter in the range from 270 nm to 300 nm.

5. The device according to claim 1, wherein the light-emitting diodes are based on a III-V or II-VI compound.

6. The device according to claim 1, wherein the light-emitting diodes are separated by an electrically-insulating material having a refraction index in the range from 1.3 to 1.6, preferably from 1.45 to 1.56.

7. The device according to claim 1, wherein one of the second, third, and fourth wavelengths is in the range from 430 nm to 480 nm, wherein another one of the second, third, and fourth wavelengths is in the range from 510 nm to 570 nm, and wherein still another one of the second, third, and fourth wavelengths is in the range from 600 nm to 720 nm.

8. The device according to claim 1, wherein the emission spectrum of the active area has energy at the second wavelength.

9. The device according to claim 8, further comprising a first optical filter covering at least a first portion of said array of light-emitting diodes, the first optical filter being configured to block said amplified radiation over a first wavelength range comprising the first, third, and fourth wavelengths and to give way to said amplified radiation over a second wavelength range comprising the second wavelength.

10. The device according to claim 8, wherein the emission spectrum of the active area has energy at the third wavelength.

11. The device according to claim 10, further comprising a second optical filter covering at least a second portion of said array of light-emitting diodes, the second optical filter being configured to block said amplified radiation over a third wavelength range comprising the first, second, and fourth wavelengths and to give way to said amplified radiation over a fourth wavelength range comprising the third wavelength.

12. The device according to claim 10, wherein the emission spectrum of the active area has energy at the fourth wavelength.

13. The device according to claim 12, further comprising a third optical filter covering at least a third portion of said array of light-emitting diodes, the third optical filter being configured to block said amplified radiation over a fifth wavelength range comprising the first, second, and third wavelengths and to give way to said amplified radiation over a sixth wavelength range comprising the fourth wavelength.

14. The device according to claim 1, comprising a support having the light-emitting diodes resting thereon, each light-emitting diode comprising a stack of a first semiconductor portion resting on the support, of the active area in contact with the first semiconductor portion, and of a second semiconductor portion in contact with the active area.

15. The device according to claim 14, wherein the second semiconductor portions of the light-emitting diodes are covered with an electrically-conductive layer at least partly transparent to the radiation emitted by the light-emitting diodes.

16. The device according to claim 1, wherein at least one of the resonance peaks is attenuated with respect to the other resonance peaks.

17. The device according to claim 16, comprising a support having the light-emitting diodes resting thereon, each light-emitting diode comprising a stack of a first semiconductor portion resting on the support, of the active area in contact with the first semiconductor portion, and of a second semiconductor portion in contact with the active area, wherein the lateral walls of the first and second semiconductor portions of at least part of the light-emitting diodes are covered with a sheath.

18. The device according to claim 16, wherein the second semiconductor portions of the light-emitting diodes are covered with an electrically-conductive layer at least partly transparent to the radiation emitted by the light-emitting diodes, wherein a first portion of the electrically-conductive layer covering a first group of said light-emitting diodes has a first thickness and a second portion of the electrically-conductive layer covering a second group of said light-emitting diodes has a second thickness, smaller than the first thickness.

19. The device according to claim 16, wherein the light-emitting diodes of a first group of said light-emitting diodes are separated by a first electrically-insulating material having a first refraction index and the light-emitting diodes of a second group of said light-emitting diodes are separated by a second electrically-insulating material having a second refraction index different from the first refraction index.

20. A method of manufacturing an optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to be able to form three resonance peaks amplifying the intensity of said electromagnetic radiation at at least second, third, and fourth wavelengths.

21. The method according to claim 20, wherein each active area is configured to emit the electromagnetic radiation having an emission spectrum with a full width at half maximum in the range from 100 nm to 180 nm.

22. The method according to claim 20 or 21, wherein the forming of the light-emitting diodes of the array comprises the steps of:
forming second semiconductor portions on a substrate, the second semiconductor portions being separated from one another by the pitch of the array;
forming an active area on each second semiconductor portion; and
forming a first semiconductor portion on each active area.

23. The method according to claim 20, wherein the light-emitting diodes are distributed in at least first and second groups of light-emitting diodes, the method comprising the forming of a first optical filter on the first group and of a second optical filter on the second group, the second optical filter being different from the first optical filter.

24. The method according to claim 20, comprising attenuating at least one of the resonance peaks with respect to the other resonance peaks after the forming of the light-emitting diodes.
